(19) United States
(12) Patent Application Publication
(10) Pub. No.: US 2012/0280368 A1
(43) Pub. Date: Nov. 8, 2012

(54) LAMINATED STRUCTURE FOR SEMICONDUCTOR DEVICES

(76) Inventors: Sean Matthew Garner, Elmira, NY (US); Mingqian He, Horseheads, NY (US); Joydeep Lahiri, Painted Post, NY (US); Jianfeng Li, (US); Michael Lesley Sorensen, Waverly, NY (US); Wendell P. Weeks, Corning, NY (US)

(21) Appl. No.: 13/461,931

(22) Filed: May 2, 2012

Related U.S. Application Data
(60) Provisional application No. 61/483,175, filed on May 6, 2011.

(51) Int. Cl. H01L 29/02; H01L 21/20; B32B 17/00

(52) U.S. Cl. 257/629; 428/428; 438/479; 257/E29.002; 257/E21.09

(57) ABSTRACT

Articles are described utilizing laminated glass substrates, for example, ion-exchanged glass substrates, with flexible glass or polymers and with semiconductor devices which may be sensitive to alkali migration are described along with methods for making the articles.

This application claims the benefit of priority under 35 U.S.C. §120 of U.S. Application Ser. No. 61/483175 filed on May 6, 2011 the content of which is relied upon and incorporated herein by reference in its entirety.

### BACKGROUND

1. Field

Embodiments relate generally to articles using laminated structures and more particularly to semiconductor devices using strengthened glass as backplane substrates with flexible glass layers or polymer layers and methods of making the same.

2. Technical Background

As semiconductor devices, such as e-readers, display devices, photovoltaic devices, thin-film transistors (TFTs) and other electronic gadgetry continue to gain worldwide acceptance, the demand for higher device mechanical durability grows. For those current products using glass as the backplane substrate, an impact with the floor, harsh environmental conditions, or similar event could cause device failure. For example, fracturing of the glass backplane substrate is a dominant failure mode in current e-readers.

Glass is viewed by device manufacturers as limiting the device durability, and attempts have been made to replace it with other materials such as metal sheets (e.g. aluminum or stainless steel) and polymer films (polyethylene terephthalate or polyethylene naphthalate). Although metal and polymer films are non-brittle, these materials also have limitations. Metal films are often too rough and require a planarization layer. Polymer films are prone to solvent incompatibility and have thermal-dimensional limitations.

The ideal substrate would be able to withstand increased temperatures, provide a surface with low roughness, be unaffected by processing solvents, and be able to withstand everyday final product-type abuse. If it had higher durability than the typically incorporated backplane glass substrates, glass would be the ideal substrate choice.

It would be advantageous to create a mechanically durable semiconductor device backplane using laminated structures, for example, laminated structures using strengthened glass substrates without the disadvantage of alkali metal ion contamination.

### SUMMARY

One possibility is to use strengthened glass, such as Gorilla® (registered Trademark of Corning Incorporated) Glass as the backplane substrate. Ion-exchanged Gorilla® Glass, however, is sodium and potassium rich on the surface and alkali metal is a disadvantage in semiconductor device operation and fabrication, for example, TFT manufacturing. Free alkali metal ions can contaminate typical silicon (Si) TFT devices, and alkali containing glass is to be avoided in the typical high temperature vacuum processing steps used to make Si TFTs. The use of alkali-free glass is acceptable for Si TFT fabrication, but alkali-free glass currently does not have the mechanical reliability of strengthened glass, for example, ion-exchanged glass. On the other hand, organic TFTs do not require high temperature processing. If a suitable alkali ion barrier existed, semiconductor devices, for example, organic TFTs could be fabricated onto a mechanically durable strengthened glass, for example, an ion-exchanged substrate.

One embodiment is an article comprising a glass substrate having a first surface and a second surface, wherein the substrate is an alkali containing glass, and a flexible glass layer having a capability of bending to a radius of 30 cm or greater and having a first surface and a second surface, wherein the first surface of the flexible glass layer is adjacent to the second surface of the glass substrate, and wherein the layer is an alkali-free glass.

Another embodiment is an article comprising a glass substrate having a first surface and a second surface; a flexible glass layer having a capability of bending to a radius of 3 centimeters (cm) or greater and having a first surface and a second surface, wherein the first surface of the flexible glass layer is adjacent to the second surface of the glass substrate; and a device comprising a semiconductor film adjacent to the second surface of the flexible glass layer.

Another embodiment is an article comprising a strengthened glass substrate having a first surface and a second surface and having a Vickers crack initiation threshold of at least 20 kilogram force (kgf); a polymer layer having a first surface and a second surface, wherein the first surface of the polymer layer is adjacent to the second surface of the strengthened glass substrate; and a device comprising a semiconductor film adjacent to the second surface of the polymer layer.

Another embodiment is a method comprising providing a glass substrate having a first surface and a second surface; applying a flexible glass layer having a capability of bending to a radius of 3 cm or greater and having a first surface and a second surface, wherein the first surface of the flexible glass layer is adjacent to the second surface of the glass substrate; and forming a device comprising a semiconductor film adjacent to the second surface of the flexible glass layer.

Another embodiment is a method comprising providing a strengthened glass substrate having a first surface and a second surface and having a Vickers crack initiation threshold of at least 20 kgf; applying a polymer layer having a first surface and a second surface, wherein the first surface of the polymer layer is adjacent to the second surface of the strengthened glass substrate; and forming a device comprising a semiconductor film adjacent to the second surface of the polymer layer.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of an article according to one embodiment.

FIG. 2 is an illustration of an article according to one embodiment.

FIG. 3 is an illustration of an article according to one embodiment.

FIG. 4 is a side view illustration showing a bottom-gate top-contact (BG-TC) TFT device.

FIG. 5 is a side view illustration showing a bottom-gate bottom-contact (BG-BC) TFT device.

FIG. 6 is a side view illustration showing a top-gate bottom-contact (TG-BC) TFT device.

FIG. 7 is a side view illustration showing a top-gate top-contact (TG-TC) TFT device.

FIG. 8 is a photograph of an Electrophoretic Display (EPD) laminated on a thin flexible glass layer with an organic thin-film transistor (OTFT) device.

FIG. 9 is a graph showing ring on ring load failures of exemplary ion-exchanged glass substrates at various thicknesses.

### DETAILED DESCRIPTION

Reference will now be made in detail to various embodiments.

As used herein, the term “substrate” can be used to describe either a substrate or a superstrate depending on the configuration of the device. For example, the substrate is a superstrate, if when assembled into, for example, a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

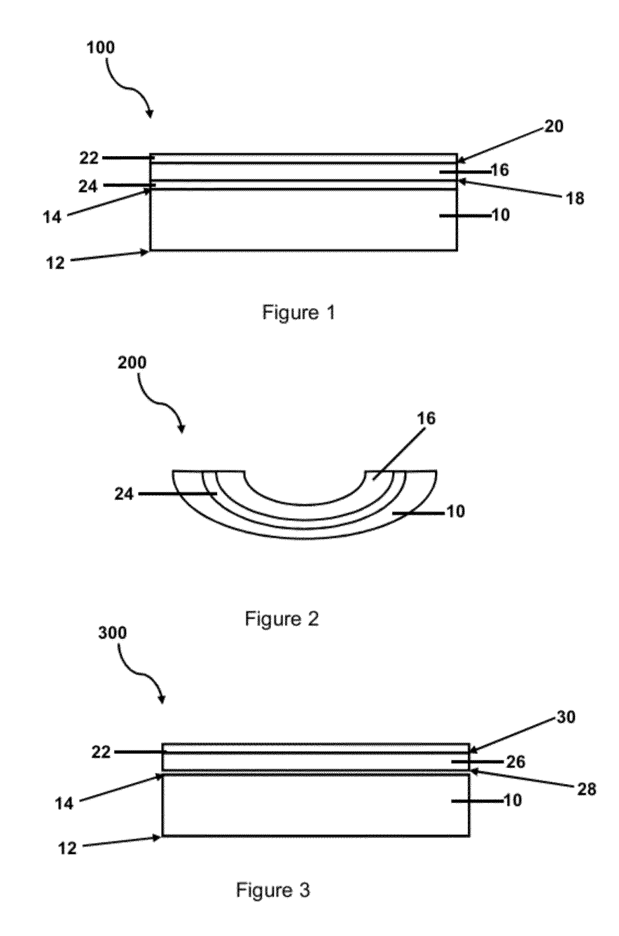

One embodiment, as shown in FIG. 1, is an article 100 comprising a glass substrate 10 having a first surface 12 and a second surface 14, wherein the substrate is an alkali containing glass, and a flexible glass layer 16 having a capability of bending to a radius of 30 cm or greater and having a first surface and a second surface, wherein the first surface of the flexible glass layer is adjacent to the second surface of the glass substrate, and wherein the layer is an alkali-free glass. A semiconductor film can be adjacent to the flexible glass layer or can be disposed on the flexible glass layer. In some embodiments, the semiconductor film is in a device comprising the semiconductor film. In one embodiment, the article is the backplane in, for example, e-readers, display devices, photovoltaic devices, or a TFT device.

One embodiment, as shown in FIG. 1, is an article 100 comprising a glass substrate 10 having a first surface 12 and a second surface 14; a flexible glass layer 16 having a capability of bending to a radius of 30 cm or greater and having a first surface 18 and a second surface 20, wherein the first surface 18 of the flexible glass layer 16 is adjacent to the second surface 14 of the glass substrate 10; and a device 22 comprising a semiconductor film adjacent to the second surface 20 of the flexible glass layer 16.

In one embodiment, the flexible glass layer is disposed on the glass substrate, for example, the flexible glass layer is in physical contact with the glass substrate. The flexible glass layer, in one embodiment, is an alkali-free glass. Alkali-free glass can be free of intentionally added alkali (for example, in the glass composition as batched) or for example, have an alkali content of 0.05 weight percent or less, for 0 weight percent alkali. The flexible glass layer can be in the form of a glass sheet. In one embodiment, the flexible glass layer or sheet is transparent.

The flexible glass layer can be made from an alkali-free glass composition and drawn to thicknesses of <300 microns (um). For example, the flexible glass can have an average thickness of 300 um or less, for example, 200 um or less, for example, 100 um or less, for example, 50 um or less. In one embodiment, the flexible glass layer has an average thickness of 150 um or less. The flexible glass could have the dimensional tolerances and surface quality of typical fusion drawn liquid crystal display (LCD) substrates to enable the fabrication of high performance TFT on its surface. In some embodiments, the flexible glass is capable of a minimum bend radius of 30 cm or greater, 25 cm or greater, 20 cm or greater, 15 cm or greater, 10 cm or greater, 5 cm or greater, 3 cm or greater, or 1 cm or greater. The flexible glass is capable of this minimum bend radius without cracking, shattering, and/or breaking.

In one embodiment, the device is disposed on the flexible glass layer, for example, the device is in physical contact with the flexible glass layer.

The article, according to one embodiment and shown in FIG. 1, further comprises an optional bonding layer 24 disposed between the flexible glass layer 16 and the glass substrate 10. When the bonding layer is present, in one embodiment, the bonding layer is a laminate layer and the flexible glass layer is laminated to the glass substrate. This laminate layer could be an organic or non-organic adhesive film. As another example, the bonding layer 24 could be a photo or thermally curing adhesive layer. Pressure sensitive adhesives, photo curable organic adhesives, silicone films and thermally curing adhesives, inorganic layers such as frits are examples of bonding layer 24.

In one embodiment, the glass substrate is in the form of a glass sheet. The glass substrate, in one embodiment, comprises a strengthened glass having a Vickers crack initiation threshold of at least 20 kgf. The glass substrate can be an ion-exchanged glass. The glass substrate can be planar or non-planar, for example, the glass substrate can be curved with a single or variable radius.

According to some embodiments, the glass substrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass substrate can have a thickness of any numerical value including decimal places in the range of from 0.1 mm up to and including 4.0 mm.

In one embodiment, a functional layer is disposed on the first surface of the glass substrate. The functional layer can be selected from an anti-glare layer, an anti-smudge layer, a self-cleaning layer, an anti-reflection layer, an anti-fingerprint layer, an optically scattering layer, and combinations thereof.

Another embodiment, as shown in FIG. 3 is an article 300 comprising a strengthened glass substrate 10 having a first surface 12 and a second surface 14 and having a Vickers crack initiation threshold of at least 20 kgf; a polymer layer 26 having a first surface 28 and a second surface 30, wherein the first surface 28 of the polymer layer 26 is adjacent to the second surface 14 of the strengthened glass substrate 10; and a device 22 comprising a semiconductor film adjacent to the second surface 30 of the polymer layer 26.

In one embodiment, the strengthened glass substrate is in the form of a glass sheet. The strengthened glass substrate can be an ion-exchanged glass. The strengthened glass substrate can be planar or non-planar, for example, the strengthened glass substrate can be curved with a single or variable radius. As shown in FIG. 2, the flexible glass substrate 16 can be bonded to the concave surface of the curved strengthened glass substrate 10. An alternative example not shown is that the flexible glass substrate 16 can also be bonded to the convex surface of the curved strengthened glass substrate 10.

Glasses designed for use in applications such as in consumer electronics and other areas where high levels of damage resistance are desirable are frequently strengthened by thermal means (e.g., thermal tempering) or chemical means. Ion-exchange is widely used to chemically strengthen glass articles for such applications. In this process, a glass article containing a first metal ion (e.g., alkali cations in Li₂O, Na₂O, etc.) is at least partially immersed in or otherwise contacted with an ion-exchange bath or medium containing a second metal ion that is either larger or smaller than the first metal ion that is present in the glass. The first metal ions diffuse from the glass surface into the ion-exchange bath/medium while the second metal ions from the ion-exchange bath/medium replace the first metal ions in the glass to a depth of layer below the surface of the glass. The substitution of larger ions for smaller ions in the glass creates a compressive stress at the glass surface, whereas substitution of smaller ions for larger ions in the glass typically creates a tensile stress at the surface of the glass. In some embodiments, the first metal ion and second metal ion are monovalent alkali metal ions. However, other monovalent metal ions such as Ag⁺, Tl⁺, Cu⁺, and the like may also be used in the ion-exchange process.

In one embodiment, the glass substrate is an alkali containing glass, for example, the glass has at least one intentionally added alkali metal such as K, Na, Li, Cs, or Rb. In one embodiment, the glass substrate comprises K, Na, or a combination thereof. The glass substrate can comprise greater than zero weight percent alkali, for example, greater than 5, for example, greater than 10, for example, greater than 12, for example, greater than 15, for example, greater than 20 weight percent alkali, for example greater than zero to 25 weight percent alkali. In one embodiment, the glass substrate is a soda lime glass, an aluminoborosilicate, an alkalialuminoborosilicate, an aluminosilicate, or an alkalialuminosilicate. In one embodiment, the glass substrate is a strengthened glass substrate. In one embodiment, the strengthened glass substrate is an ion-exchanged glass substrate.

In one embodiment, the glass substrate comprises a strengthened glass wherein the glass is ion-exchanged to a depth of layer of at least 20 um from a surface of the glass.

In one embodiment, the strengthened glass substrates described herein, when chemically strengthened by ion-exchange, exhibit a Vickers initiation cracking threshold of at least about 5 kgf (kilogram force), in some embodiments, at least about 10 kgf, in some embodiments and, in other embodiments, at least about 20 kgf, for example, at least about 30 kgf. FIG. 9 is a graph showing ring on ring load failures of exemplary ion-exchanged glass substrates, for example, Gorilla® glass at various thicknesses.

In one embodiment, a functional layer is disposed on the first surface of the strengthened glass substrate. The functional layer can be selected from an anti-glare layer, an anti-smudge layer, a self-cleaning layer, an anti-reflection layer, an anti-fingerprint layer, an anti-splintering layer, an optically scattering layer, and combinations thereof.

Another embodiment is a method comprising providing a glass substrate having a first surface and a second surface; applying a flexible glass layer having a capability of bending to a radius of 3 cm or greater and having a first surface and a second surface, wherein the first surface of the flexible glass layer is adjacent to the second surface of the glass substrate; and forming a device comprising a semiconductor film adjacent to the second surface of the flexible glass layer.

In one embodiment, the method comprises applying a very thin layer of flexible glass sheet on an ion-exchange glass sheet. An alkali-free flexible glass sheet can be bonded with either an organic adhesive or a glass-glass bonding process, for example, a roll-to-roll method. The substantially alkali-free flexible glass sheet can effectively block the migration of alkali ions from the ion-exchanged glass sheet. The TFTs can be fabricated on the flexible glass sheet after the flexible glass sheet is bonded to the ion-exchanged glass sheet, according to one embodiment.

Another embodiment is a method comprising providing a strengthened glass substrate having a first surface and a second surface and having a Vickers crack initiation threshold of at least 20 kgf; applying a polymer layer having a first surface and a second surface, wherein the first surface of the polymer layer is adjacent to the second surface of the strengthened glass substrate; and forming a device comprising a semiconductor film adjacent to the second surface of the polymer layer.

The polymer layer can be deposited by a solution processing method. The polymer could be either thermally cured (crosslinked) or photo cured (crosslinked). The polymer layer could be both an insulation and dielectric layer for the subsequent backplane fabricated at <200° C. This method is suitable for TFTs such as those made with an organic semiconductor material.

After the flexible glass layer or the polymer layer is applied to the glass substrate, devices comprising a semiconductor film can be fabricated on the second surface of the flexible glass layer or the polymer layer. For example, an organic TFT device can include: an ion-exchanged glass substrate including the flexible glass layer or the polymer layer. On the flexible glass layer or the polymer layer a gate electrode, a dielectric layer, a drain electrode, a source electrode, and an organic semiconducting channel layer can be formed. These layers can be stacked in different sequences to form a laterally or vertically configured transistor device. The organic semiconducting channel layer includes semiconducting small molecules, oligomers and/or polymers. The dielectric layer can be composed of any organic or inorganic material that is able to be applied as a film at or below 200° C. In this way, a mechanically durable backplane is produced.

In another approach, the Si, oxide, or other TFTs can be fabricated on an alkali-free flexible glass layer before laminating the flexible glass layer to the ion-exchanged glass substrate. This allows process compatible flexible glass to be used during backplane fabrication. Bonding it then to the ion-exchanged glass produces a mechanically durable stack.

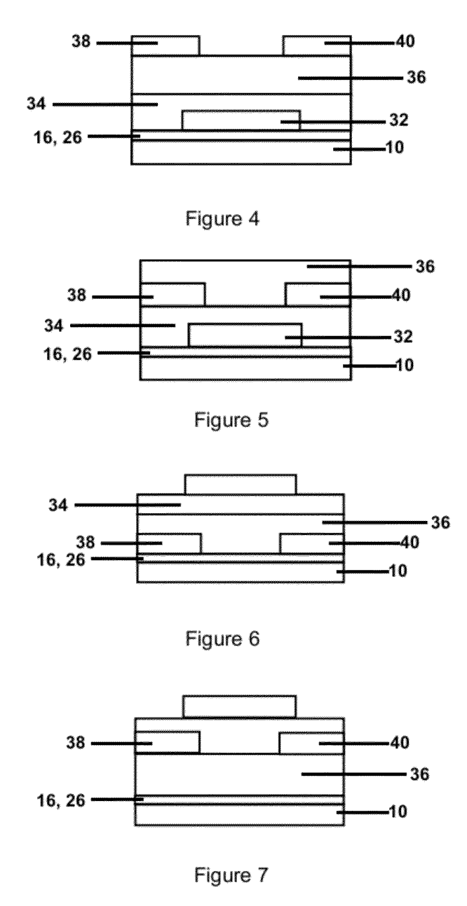

FIGS. 4-7 illustrate embodiments of articles comprising TFT devices. As used herein, the term “bottom-gate top-contact transistor” refers to a TFT device comprising an exemplary structure as shown in FIG. 4. A gate electrode 32 is deposited on a flexible glass layer or a polymer layer (16 or 26, respectively and according to any of the previously described embodiments), on a glass substrate, strengthened glass substrate, or ion-exchanged glass substrate 10 (according to any of the previously described embodiments) followed by a dielectric layer 34 and then a semiconducting layer 36. Drain and source electrodes 38 and 40, respectively, are further deposited on top of the semiconducting layer 36.

The term “bottom-gate bottom-contact transistor” refers to a TFT device comprising an exemplary structure as shown in FIG. 5. A gate electrode 32 is deposited on a flexible glass layer or a polymer layer (16 or 26, respectively and according to any of the previously described embodiments) on a glass substrate, strengthened glass substrate, or ion-exchanged glass substrate 10 (according to any of the previously described embodiments), followed by a dielectric layer 34 and then drain and source electrodes 38 and 40, respectively. A semiconducting layer 36 is further deposited on top of these underlying layers.

The term “top-gate bottom-contact transistor” refers to a TFT device comprising an exemplary structure as shown in FIG. 6. Drain and source electrodes 38 and 40, respectively are deposited on a flexible glass layer or a polymer layer (16 or 26, respectively and according to any of the previously described embodiments) on a glass substrate, strengthened glass substrate, or ion-exchanged glass substrate 10 (according to any of the previously described embodiments). A semiconducting layer 36 is then deposited on top, followed by a dielectric layer 34 and then a gate electrode 32.

The term “top-gate top-contact transistor” refers to a TFT device comprising an exemplary structure as shown in FIG. 7. A semiconducting layer 36 is deposited on a flexible glass layer or a polymer layer (16 or 26, respectively and according to any of the previously described embodiments) on a glass substrate, strengthened glass substrate, or ion-exchanged glass substrate 10 (according to any of the previously described embodiments), followed by drain and source electrodes 38 and 40, respectively. A dielectric layer 34 is further deposited on top, followed by a gate electrode 32.

### EXAMPLE 1

### Organic Bottom Gate, Top-Contact TFT on Ion-Exchange Glass

A TFT device can be fabricated by solution casting a thin layer of organic semiconducting materials such as thiophene copolymers onto a polymer dielectric layer.

This exemplary method comprises cleaning ion-exchanged glass substrates by using sonication in acetone and then isoproponol; depositing a patterned gold (Au) gate electrode at 2 Angstroms per second (Å/s) for 30 nm; spin-casting a mixture of 11 weight percent (wt %) (film thickness ˜800 nanometers (nm) to 1 um) poly vinyl-phenol (PVP) solution in Propylene Glycol Methyl Ether Acetate (PGMEA) and Melamine at 1000 rotations per minute (rpm) for 30 seconds (sec); and curing this layer by ultraviolet (UV)-light for less than 3 min. The method further comprises dissolving 3 milligrams per milliliter (mg/mL) of P2TDC17FT4 (organic semiconducting polymer) in 1,2-dichlorobenzene and spin-coating the solution; annealing the whole devices at 100° C. for 30 mins on a hotplate; and depositing a Au source electrode and drain electrode at 2 Å/s for 30 nm.

### EXAMPLE 2

### Bonding Flexible Glass Layer to an Ion-Eexchanged Glass Substrate and Fabricating a Transistor on the Flexible Glass Layer

As mentioned previously, a flexible glass substrate can be bonded to a mechanically durable ion-exchanged glass substrate to produce a composite structure. This composite structure offers the alkali-free flexible glass surface for high quality TFT fabrication and performance. It also provides the high mechanical durability of the ion-exchanged glass.

The flexible glass layer can be made from an alkali-free glass composition and drawn to thicknesses of <300 um. For example, the flexible glass can have a thickness of 300 um or less, for example, 200 um or less, for example, 100 um or less, for example, 50 um or less. The flexible glass could have the dimensional tolerances and surface quality of typical fusion drawn LCD substrates to enable the fabrication of high performance TFT on its surface.

The ion-exchanged glass substrate can have a thickness <1.5 mm and have mechanical durability characteristics similar to those typical of Gorilla® Glass and fully integrated touch (FIT) product substrates. For example it could have a compression layer that enables backplane fabrication onto device substrate pre-cut to the final size, or it could enable backplane fabrication on substrates approximately 1 m×1 m in size or greater or similar substrates that are subsequently cut to the finished shape.

The flexible glass can be bonded to the surface of the ion-exchanged glass through lamination or other bonding methods. The flexible glass can have a size equal to the ion-exchanged glass, or the flexible glass can be much smaller and enable several discrete flexible glass pieces to be bonded across the ion-exchanged glass surface. To be compatible with the low temperature processing requirements of organic semiconductor devices, the flexible glass can be bonded using a pressure sensitive adhesive (PSA) for example made from silicone or acrylate adhesives. Typical PSA films range from 12.5 to 50 um thick. The flexible glass can also be bonded by use of a curable adhesive applied to either the flexible glass or ion-exchanged glass. This adhesive also can be thermally or UV (photo) cured.

As mentioned previously, semiconductor devices can be fabricated onto the flexible glass surface either before or after it is bonded to the ion-exchanged glass substrate. If the semiconductor devices are fabricated before bonding, the devices can be made by methods known in the art such as batch, continuous sheet-fed, or roll-to-roll methods. These methods take advantage of the dimensional stability of flexible glass compared to polymer films.

After the devices have been fully or partially fabricated, high strength cutting methods such as laser cutting can be used, if needed, to singulate individual device substrates. This enables a device backplane that is mechanically durable with both high strength surfaces and edges.

### EXAMPLE 3

### Organic TFT Device Built on Flexible Glass Layers

To demonstrate the ability of fabricating organic semiconductor devices on flexible glass, an organic TFT backplane was fabricated on 100 um thick flexible glass substrates. The fabrication of the OTFTs began with an organic hard coating which was spin-coated on the flexible glass as an adhesion promoter. The source and drain electrodes were formed by thermal-evaporated gold on the organic hard coating. The highly air-stable polymer semiconductor was then spin-coated and patterned by photolithography. A dielectric layer of 510 nm thick poly vinyl-phenol (PVP) was deposited and subsequently the gate electrode made of 50 nm gold metal was formed. Finally, 30 nm-thick organic interlayer film were spin-coated and the patterning of this film was done by photolithography again. Note that the via-holes through the interlayer and the dielectric to drain electrode were done by inductively coupled plasma reactive ion etcher. When fabricating the 4.7 inch backplanes on the flexible glass, it was noticed that the low thermal expansion enabled better registration between the separate photolithography processes compared to previous devices built on polyethylene napthalate (PEN) substrates.

After the backplane was fabricated, an EPD film provided by Sipix Imaging Inc. was laminated to form an AM-EPD device. A thermal lamination process was used to integrate EPD front plane on OTFTs with a laminating temperature of 100° C.

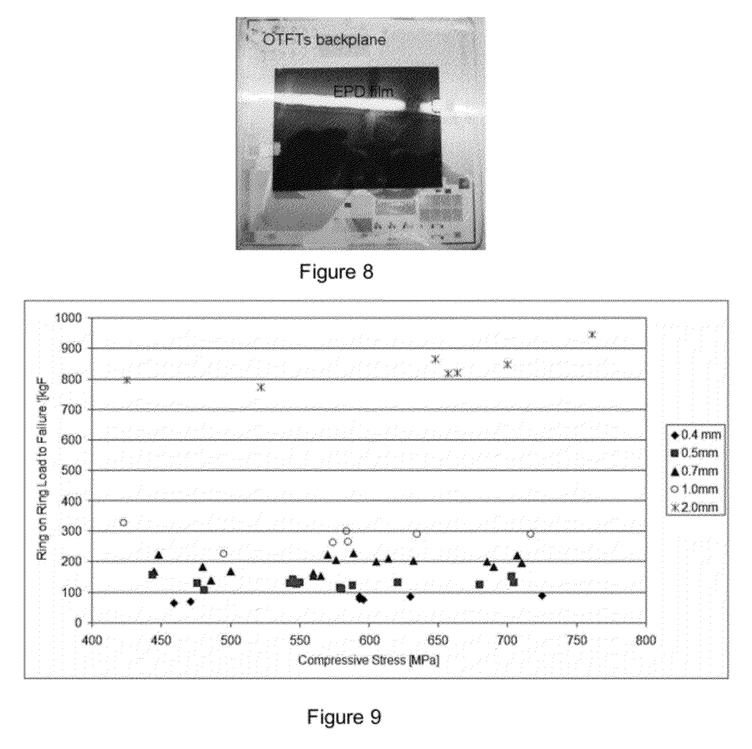

FIG. 8 is a photograph of an Electrophoretic Display (EPD) laminated on a thin flexible glass layer with an organic thin-film transistor (OTFT) device.

Embodiments described herein may provide one or more of the following advantages: provide a practical way to fabricate TFTs and circuits on strengthened glass, for example, ion-exchanged glass substrates and promote the use of strengthened glass, for example, ion-exchanged glass as suitable substrates for display backplanes; allow the fabrication of electronic devices on strengthened glass, for example, ion-exchanged glasses without changing the superior compression strength of the glass; and/or provides an easy way to minimize the migration of ions on the ion-exchanged glasses into the electronic devices' active layer.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. An article comprising:
a glass substrate having a first surface and a second surface, wherein the substrate is an alkali containing glass; and
a flexible glass layer having a capability of bending to a radius of 30 cm or greater and having a first surface and a second surface, wherein the first surface of the flexible glass layer is adjacent to the second surface of the glass substrate, and wherein the layer is an alkali-free glass.

2. The article according to claim 1, wherein the glass substrate is a strengthened glass.

3. The article according to claim 2, wherein the glass substrate is an ion-exchanged glass.

4. The article according to claim 1, further comprising a semiconductor film adjacent to the second surface of the flexible glass layer.

5. An article comprising:
a glass substrate having a first surface and a second surface;
a flexible glass layer having a capability of bending to a radius of 30 cm or greater and having a first surface and a second surface, wherein the first surface of the flexible glass layer is adjacent to the second surface of the glass substrate; and
a device comprising a semiconductor film adjacent to the second surface of the flexible glass layer.

6. The article according to claim 5, wherein the glass is a soda lime glass, an aluminoborosilicate, an alkalialuminoborosilicate, an aluminosilicate, or an alkalialuminosilicate.

7. The article according to claim 5, wherein the flexible glass layer is disposed on the glass substrate.

8. The article according to claim 5, wherein the device is disposed on the flexible glass layer.

9. The article according to claim 5, further comprising a bonding layer disposed between the flexible glass layer and the glass substrate.

10. The article according to claim 9, wherein the bonding layer is a laminate layer and the flexible glass layer is laminated to the glass substrate.

11. The article according to claim 5, wherein the flexible glass layer is an alkali-free glass.

12. The article according to claim 5, wherein the flexible glass layer is a glass sheet.

13. The article according to claim 5, wherein the glass substrate is a glass sheet.

14. The article according to claim 5, the glass substrate comprises a strengthened glass wherein the glass is ion-exchanged to a depth of layer of at least 20 um from a surface of the glass.

15. The article according to claim 5, wherein the glass substrate is an ion-exchanged glass.

16. The article according to claim 5, wherein the glass substrate has a Vickers crack initiation threshold of at least 20 kgf.

17. The article according to claim 5, further comprising a functional layer disposed on the first surface of the glass substrate.

18. The article according to claim 17, wherein the functional layer is selected from an anti-glare layer, an anti-smudge layer, a self-cleaning layer, an anti-reflection layer, an anti-fingerprint layer, an optically scattering layer, and combinations thereof.

19. The article according to claim 5, wherein the glass substrate is curved.

20. The article according to claim 5, wherein the device is selected from a photovoltaic device, a thin-film transistor, a diode, and a display device.

21. An article comprising:
a strengthened glass substrate having a first surface and a second surface and having a Vickers crack initiation threshold of at least 20 kgf;
a polymer layer having a first surface and a second surface, wherein the first surface of the polymer layer is adjacent to the second surface of the strengthened glass substrate; and
a device comprising a semiconductor film adjacent to the second surface of the polymer layer.

22. The article according to claim 21, wherein the polymer layer comprises a thermally or photo curable material.

23. The article according to claim 21, wherein the strengthened glass substrate is an ion-exchanged glass.

24. The article according to claim 21, further comprising a functional layer disposed on the first surface of the strengthened glass substrate.

25. The article according to claim 21, wherein the functional layer is selected from an anti-glare layer, an anti-smudge layer, a self-cleaning layer, an anti-reflection layer, an anti-fingerprint layer, an optically scattering layer, and combinations thereof.

26. The article according to claim 21, wherein the strengthened glass substrate is curved.

27. The article according to claim 21, wherein the device is selected from a photovoltaic device, a thin-film transistor, a diode, and a display device.

28. A method comprising:
providing a glass substrate having a first surface and a second surface;
applying a flexible glass layer having a capability of bending to a radius of 30 cm or greater and having a first surface and a second surface, wherein the first surface of the flexible glass layer is adjacent to the second surface of the glass substrate; and
forming a device comprising a semiconductor film adjacent to the second surface of the flexible glass layer.

29. The method according to claim 28, wherein the flexible glass layer comprises an alkali-free glass and wherein the applying the flexible glass layer comprises disposing the alkali-free glass on the glass substrate prior to forming the device.

30. The method according to claim 28, wherein the flexible glass layer comprises an alkali-free glass and wherein the applying the flexible glass layer comprises disposing the alkali-free glass on the glass substrate after forming the device.

31. The method according to claim 28, wherein the applying the flexible glass layer to the glass substrate comprises rolling the layer and the substrate together such that a vacuum bond is formed between the layer and the sheet.

32. The method according to claim 28, wherein the applying comprises laminating or adhesively bonding the alkali-free glass to the glass substrate.

33. A method comprising:
providing a strengthened glass substrate having a first surface and a second surface and having a Vickers crack initiation threshold of at least 20 kgf;
applying a polymer layer having a first surface and a second surface, wherein the first surface of the polymer layer is adjacent to the second surface of the strengthened glass substrate; and
forming a device comprising a semiconductor film adjacent to the second surface of the polymer layer.
